(19) United States
(12) Patent Application Publication
(10) Pub. No.: US 2014/0374892 A1
(43) Pub. Date: Dec. 25, 2014

(54) LEAD FRAME AND SEMICONDUCTOR DEVICE USING SAME

(71) Applicants: Yit Meng Lee, Malaysia (MY); Yin Kheng Au, Malaysia (MY); Quentin D. Gunn, Munich (DE)

(72) Inventors: Yit Meng Lee, Malaysia (MY); Yin Kheng Au, Malaysia (MY); Quentin D. Gunn, Munich (DE)

(21) Appl. No.: 13/924,623

(22) Filed: Jun. 24, 2013

(51) Int. Cl. H01L 23/495; H01L 23/00

(52) U.S. Cl. CPC H01L 23/4951; H01L 24/89
USPC 257/676; 438/123; 174/261

(57) ABSTRACT

A lead frame for a semiconductor device has a die pad for supporting a semiconductor die and intermediate lead fingers extending from a periphery of the package towards the die pad, and each having a bonding end near the die pad. Outer lead fingers are located adjacent respective tie bars edges, each outer lead finger extending from the periphery of the package towards the die pad. Each outer lead finger has a transverse region coupling two spaced longitudinal regions. The two spaced longitudinal regions each have a bonding region near the die pad. A semiconductor die is attached to the die pad and bond wires electrically couple connection pads of the semiconductor die to the bonding regions of each outer lead finger. Only one of the bond wires is bonded to the bonding region of the second longitudinal region.

### BACKGROUND OF THE INVENTION

The present invention relates to integrated circuit packaging and, more particularly, to a lead frame and a semiconductor device packaged with the lead frame and method of packaging a semiconductor die.

A semiconductor die is an integrated circuit formed on a semiconductor wafer, such as a silicon wafer. Such a die is typically cut from the wafer and packaged, often using a lead frame. The lead frame is a metal frame, usually of copper or nickel alloy, that supports the die and provides external electrical connections for the packaged die or chip. The lead frame usually includes a flag (die pad), and associated proximal lead fingers (leads). The semiconductor die is attached to the flag and bond pads on the die are electrically connected to the lead fingers of the lead frame with bond wires. The die and bond wires are encapsulated with a protective encapsulation compound to form a semiconductor package. The encapsulation compound defines the package body. The lead fingers either project outwardly from the body or are at least flush with the body so they can be used as terminals, allowing the semiconductor package to be electrically connected directly to other devices or to a printed circuit board (PCB).

Semiconductor dies are being fabricated with an increased functionality, which requires an increased pin count, but at the same time, it is still desirable to have a small package size, making it difficult to accommodate additional pins (external terminals). This is partly because of improved silicon die fabrication techniques that allow die size reductions. However, the number of lead fingers is limited by the size of the package and the pitch of the lead fingers. When the flag (die pad) is downset from the lead fingers, the lead frame and angled sections of the associated tie bars are located in a recess and slots of a lead frame support that is typically a heater block. However, some of the lead fingers can be located relatively close to the tie bars and due to positioning tolerances (or indexing inaccuracy) a bonding end of a lead finger may be unsupported over one of the slots. This unsupported bonding end is subject to stress, bounce and bending during wire bonding. Consequently, this may lead to poor quality or faulty wire bonds especially when more than one wire bond is required at the unsupported bonding end. Thus, it would be advantageous to improve bond quality for currently unsupported bond ends (lead tips).

### BRIEF DESCRIPTION OF THE DRAWINGS

The invention, together with objects and advantages thereof, may best be understood by reference to the following description of preferred embodiments together with the accompanying drawings in which:

FIG. 1 is a plan view of a lead frame support that is typically a heating block;

FIG. 2 is a plan view of an conventional lead frame positioned and supported on the lead frame support of FIG. 1;

FIG. 3 is a plan view of a lead frame, according an embodiment of the present invention, when positioned and supported on the lead frame support of FIG. 1;

FIG. 4 is a plan view of a partially assembled semiconductor package, formed on the lead frame of FIG. 3 when positioned and supported on the lead frame support of FIG. 1;

FIG. 5 is a plan view of the partially assembled semiconductor package of FIG. 4, showing a wire bonding step, while positioned and supported on the lead frame support of FIG. 1;

FIG. 6 is a plan view of the semiconductor package of FIG. 5 after encapsulation, in accordance with a preferred embodiment of the present invention;

FIG. 7 is a plan view of the semiconductor package of FIG. 6 after detaching and trimming and forming steps, in accordance with a preferred embodiment of the present invention;

FIG. 8 is a partial side view of the semiconductor package of FIG. 7;

FIG. 9 is a plan view of a lead frame according to another embodiment of the present invention, when positioned and supported on the lead frame support of FIG. 1; and

FIG. 10 is a flow chart illustrating a method of forming a semiconductor package in accordance with a preferred embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practiced. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, method steps and structures that comprises a list of elements does not include only those elements but may include other elements not expressly listed or inherent to such module, circuit, steps or device components. An element or step proceeded by “comprises” does not, without more constraints, preclude the existence of additional identical elements or steps that comprises the element or step.

Certain features in the drawings have been enlarged for ease of illustration and the drawings and the elements thereof are not necessarily in proper proportion. Further, the invention is shown embodied in a quad flat pack (QFP) type package. However, those of ordinary skill in the art will readily understand the details of the invention and that the invention is applicable to all leaded package types and their variations.

In one embodiment, the present invention provides for a frame member surrounding a die pad. There are tie bars attaching the die pad to the frame member, the tie bars being bent so that die pad is downset from the frame member. There are intermediate lead fingers extending from the frame member towards the die pad, the intermediate lead fingers each having a bonding end near the die pad. One outer lead finger is adjacent a respective edge of each one of the tie bars, and each outer lead finger extends from the frame member towards the die pad. Each outer lead finger includes a transverse region coupling two spaced longitudinal regions and the two spaced longitudinal regions each have a bonding region near the die pad.

In another embodiment, the present invention provides for a method of forming a semiconductor die package, the method includes providing a lead frame with a frame member surrounding a die pad, the lead frame having tie bars attaching the die pad to the frame member. The tie bars have an angled section that downsets die pad from the frame member, and intermediate lead fingers extend from the frame member towards the die pad. There is an outer lead finger adjacent a respective edge of each one of the tie bars, and each outer lead finger extends from the frame member towards the die pad. Also, each outer lead finger includes a transverse region coupling two spaced longitudinal regions each having a bonding region near the die pad. The two spaced longitudinal regions are a first longitudinal region and second longitudinal region located between the first longitudinal region and one of the tie bars.

The method also includes attaching a semiconductor die to the die pad and selectively electrically coupling, with bond wires, connection pads of the semiconductor die to the bonding regions of each outer lead finger. This coupling is characterized by no more than one of the bond wires is bonded to the bonding region of the second longitudinal region. The method further includes encapsulating the semiconductor die and bonding regions with an encapsulating compound. There is then performed a process of detaching from the frame member the tie bars, the intermediate lead fingers, and each outer lead finger to thereby provide the semiconductor die package.

In another embodiment, the present invention provides for semiconductor die package including a semiconductor die attached to a die pad. There are intermediate lead fingers extending from a periphery of the package towards the die pad, the lead fingers intermediate each having a bonding end near the die pad. There is an outer lead finger adjacent a respective edge of each one of the tie bars, each outer lead finger extending from the periphery of the package towards the die pad. Each outer lead finger includes a transverse region coupling two spaced longitudinal regions and wherein the two spaced longitudinal regions each have a bonding region near the die pad. A semiconductor die is attached to the die pad and bond wires selectively electrically couple connection pads of the semiconductor die to the bonding regions of each outer lead finger. No more than one of the bond wires is bonded to the bonding region of the second longitudinal region and an encapsulation compound covers the bond wires and semiconductor die.

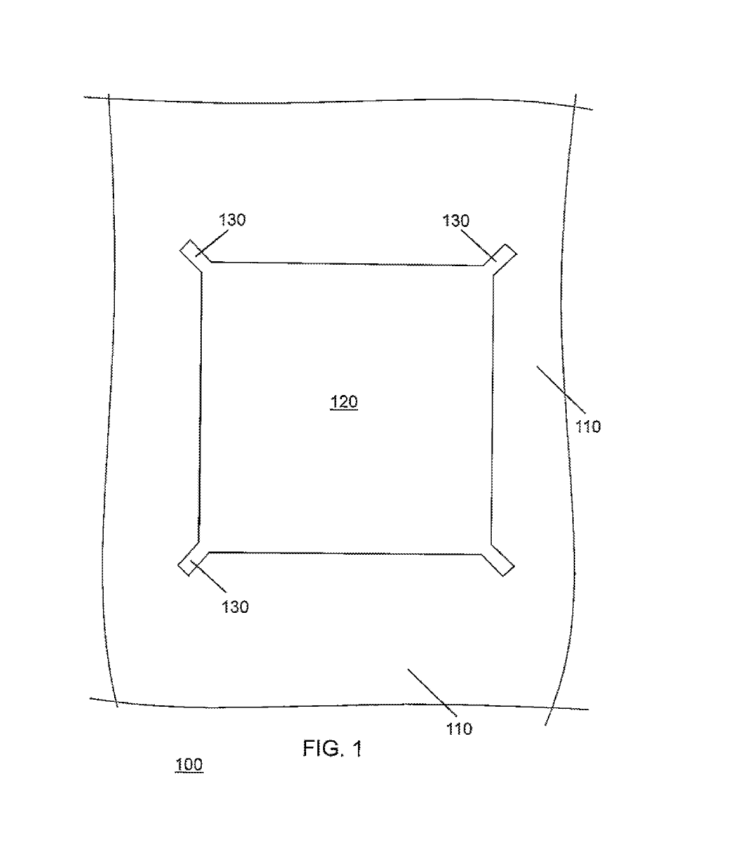

Referring to FIG. 1, a plan view of a lead frame support 100 that is typically a heating block is shown. The lead frame support 100 has an outer planar lead finger support region 110, a recessed central die pad support region 120 and slots 130 for accommodating tie bars. The lead frame support 100 is part of a larger support that has numerous such outer planar lead finger support regions 110, recessed central die pad support regions 120 and slots 130 as will be apparent to a person skilled in the art. Furthermore, the lead frame support 100 has heating elements (not illustrated) for heating the lead finger support regions 110 to facilitate wire bonding of bond wires to lead fingers supported on the lead finger support region 110.

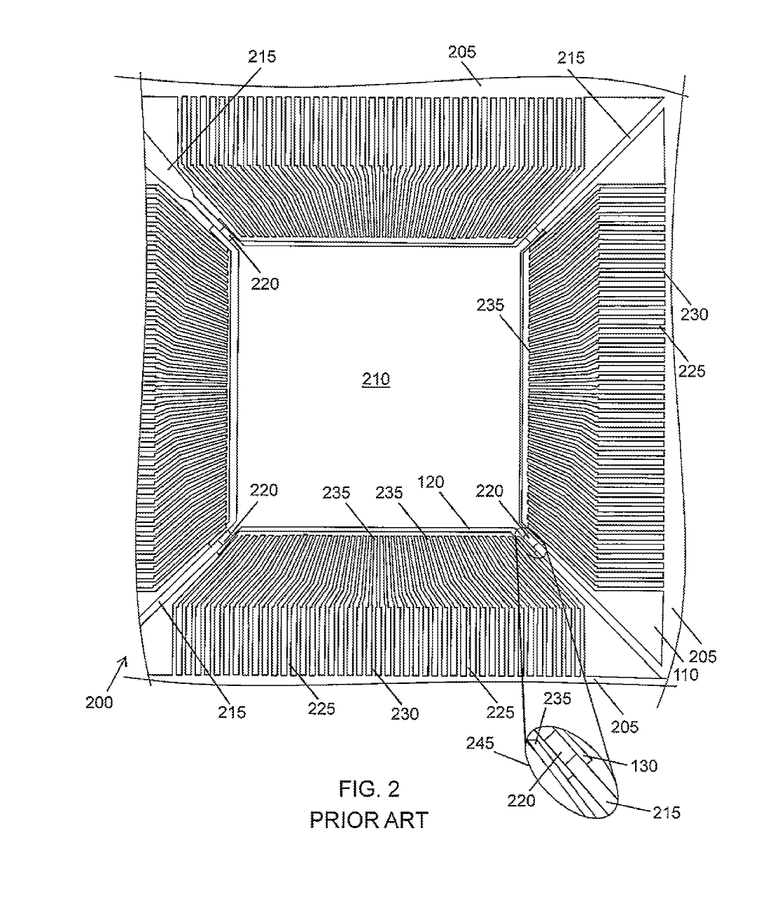

Referring to FIG. 2, a plan view of a conventional lead frame 200 positioned and supported on the lead frame support 100 is shown. The conventional lead frame 200 has a frame member 205 surrounding a die pad 210, and tie bars 215 attach the die pad 210 to the frame member 205. The tie bars 215 are bent at an angled section 220 so that die pad 210 is downset from the frame member 205 and thus the die pad 210 is located in and supported by the die pad support region 120. Similarly, each angled section 220 is located in a respective one of the slots 130. The lead frame 200 also has a plurality of lead fingers 225 supported on the lead finger support regions 110. Each of the lead fingers 225 extends from the frame member 205 towards the die pad 210, and each of the lead fingers 225 has a distal end 230 connected to the frame member 205 and a proximal or bonding end 235 near the die pad 210.

The lead fingers 225 include an outer lead finger 240 adjacent a respective edge of one of the tie bars 215. In order to increase the number of lead fingers 225, the outer lead fingers 240 can be located relatively close to the tie bars 215. Consequently, due to positioning tolerances (or indexing inaccuracy) a bonding end 235 of one or more of the outer lead fingers 240 may be unsupported over one of the slots 130 as illustrated by magnified region 245. Accordingly, the unsupported bonding end 235 is subject to stress, bounce and bending during wire bonding. This may lead to poor quality or faulty wire bonds especially when more than one wire bond is required at the unsupported bonding end 235.

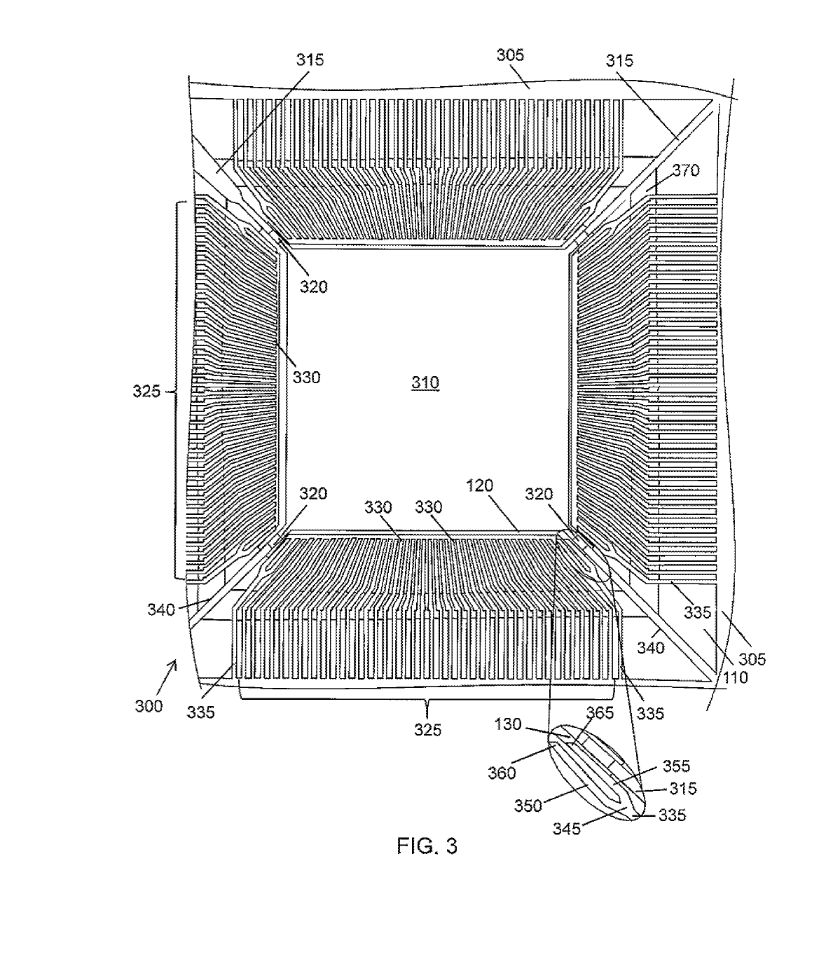

Referring to FIG. 3, a plan view of a lead frame 300 in accordance with an embodiment of the present invention, when positioned and supported on the lead frame support 100, is shown. The lead frame 300 includes a frame member 305 surrounding a die pad 310, and tie bars 315 that attach the die pad 310 to the frame member 305. The tie bars 315 are bent at an angled section 320 so that the die pad 310 is downset from the frame member 305 and thus the die pad 310 is located in and supported by the die pad support region 120. Similarly, each angled section 320 is located in a respective one of the slots 130. The lead frame 300 also has a plurality of intermediate lead fingers 325 extending from the frame member 305 towards the die pad 310, the intermediate lead fingers 325 each having a bonding end 330 near the die pad 310.

There is also an outer lead finger 335 adjacent a respective edge 340 of each one of the tie bars 315. Each outer lead finger 335 extends from the frame member 305 towards the die pad 310. Each outer lead finger 335 includes two spaced longitudinal regions namely a first longitudinal region 350 and a second longitudinal region 355, and a transverse region 345 coupling the two spaced longitudinal regions 350 and 355. The second longitudinal region 355 is located between the first longitudinal region 350 and one of the tie bars 315, and the first and second longitudinal regions 350, 355 each have a respective bonding region 360, 365 near the die pad 310.

As illustrated, each outer lead finger 335 includes a fork with the transverse region 345 located between the frame member 305 and the bonding regions 360, 365 of each of the longitudinal regions 350, 355. There is also a support tape 370, in the shape of a rectangular frame, attached to an underside of the intermediate lead fingers 325 and the longitudinal regions 350, 355. The support tape 370 provides some rigidity and restricts movement of the intermediate lead fingers 325 and outer lead fingers 335.

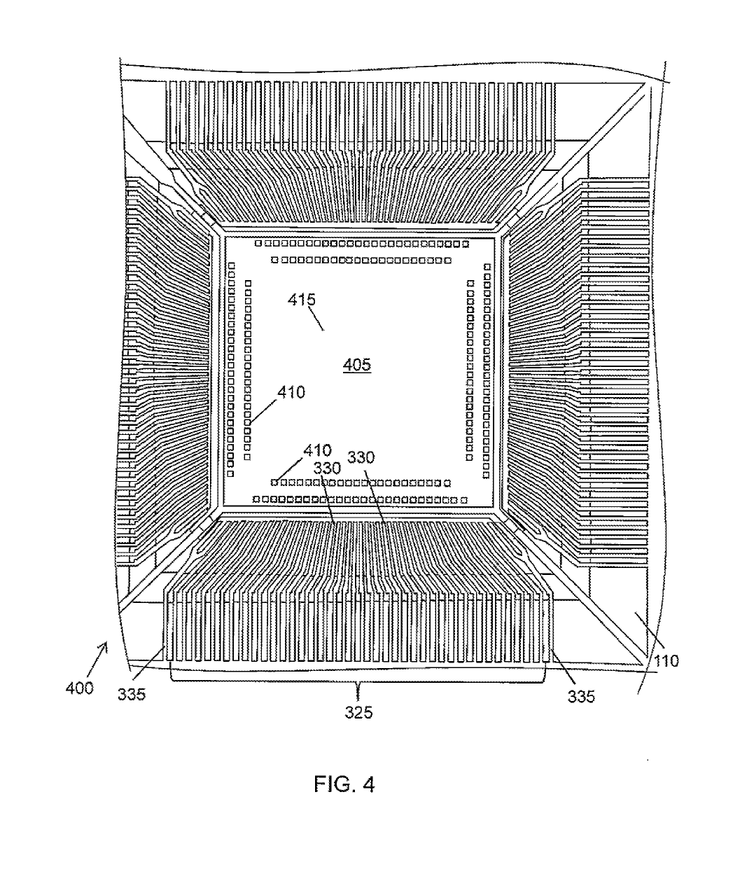

FIG. 4 is a plan view of a partially assembled package 400, formed on the electrically conductive lead frame 300 when positioned and supported on the lead frame support 100. The partially assembled package 400 includes a semiconductor die 405 attached to the die pad 310 by a bonding agent (not shown). The die 405 may be a most any type of die such as a System On a Chip (SOC), a micro-control unit (MCU), a processor, an Application Specific Integrated Circuit (ASIC), etc. The bonding agent or die attach material also is well known and the present invention is not to be limited to any particular means for attaching the die 405 to the die pad 310. Also, as various size semiconductor die are known, it is understood that the size and shape of the die pad 310 will depend on the particular semiconductor die 405. The semiconductor die 405 has connection pads 410 (that can be circuit electrodes) that are input, output or power supply nodes. The connection pads 410 are disposed on an upper or active surface 415 of the semiconductor die 405 as will be apparent to a person skilled in the art.

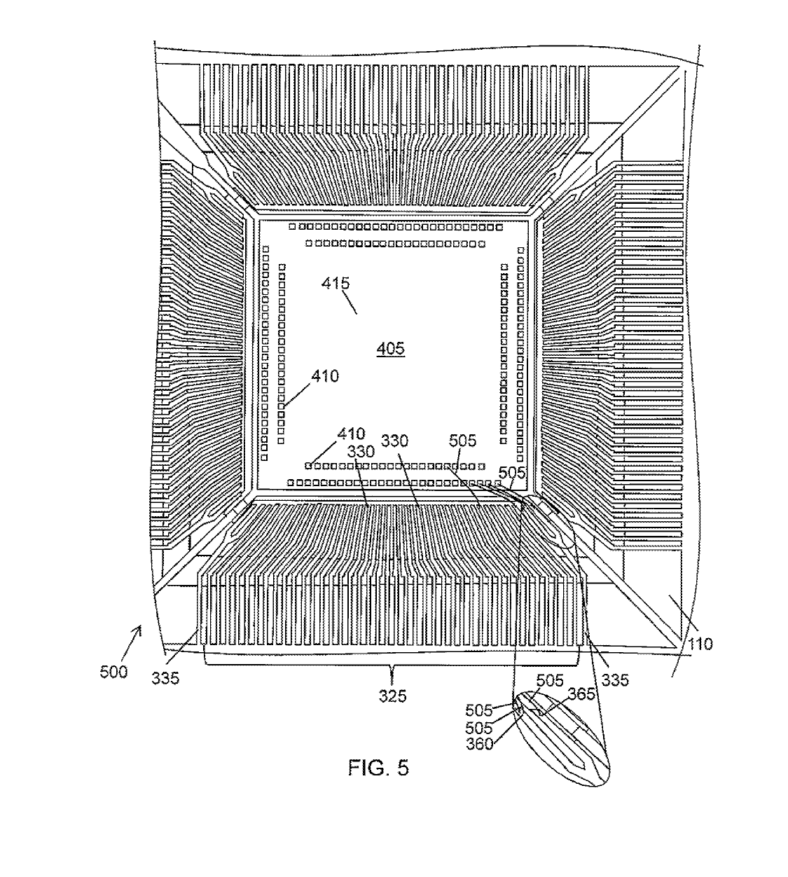

FIG. 5 is a plan view of a partially assembled package 500, formed on the electrically frame 300 when positioned and supported on the lead frame support 100. As shown, some of the connection pads 410 of the semiconductor die 405 are selectively electrically coupled to the bonding ends 330 of the intermediate lead fingers 325 by bond wires 505. Also, the connection pads 410 are selectively electrically coupled, by the bond wires 505, to the bonding regions 360, 365 such that no more than one of the bond wires 505 is bonded to the bonding region 365 of the second longitudinal region 355. In contrast, more than one of the bond wires 505 typically is bonded to the bonding region 360 of the first longitudinal region 350.

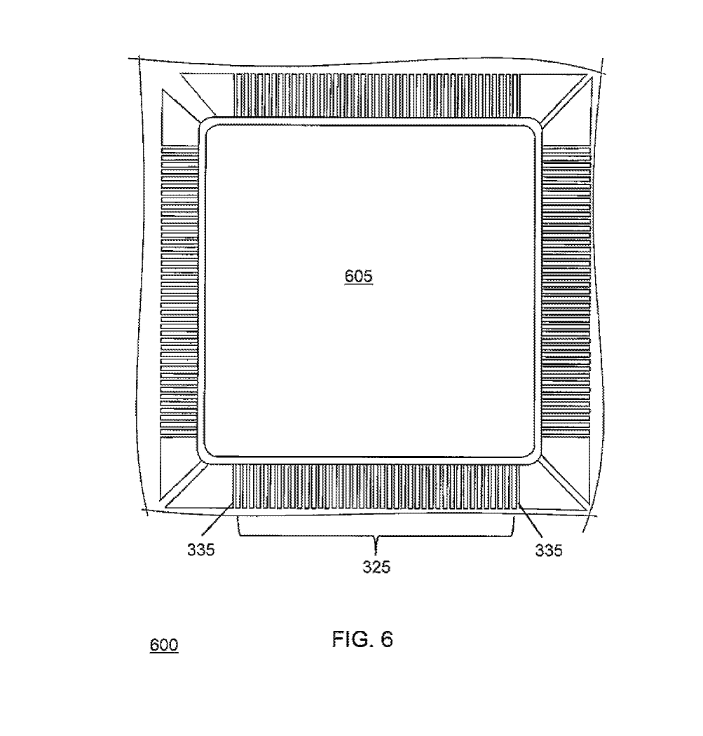

FIG. 6 is a plan view of an encapsulated semiconductor package 600 formed on the lead frame 300 after encapsulation in accordance with a preferred embodiment of the present invention. The encapsulated semiconductor package 600 includes an encapsulant 605 that has been molded to the conductive lead frame 300 thereby encapsulating the semiconductor die 405, the bonds wires 505, the bonding ends 330, bonding regions 360, 365 and the longitudinal regions 360, 365. The encapsulant 605 may comprise commercially known encapsulants typically used in semiconductor packaging, such as various plastic molding compounds.

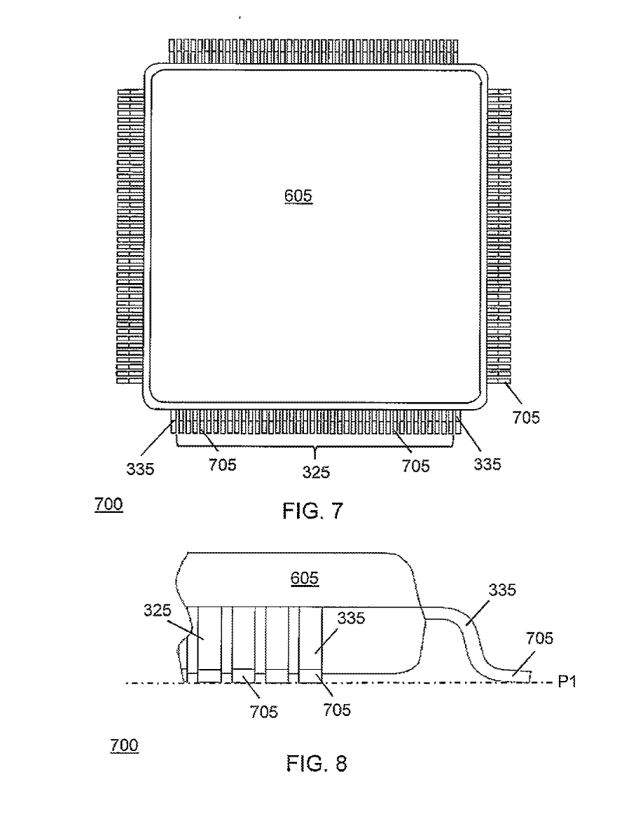

Referring to FIG. 7 there is illustrated a plan view of a semiconductor device 700 that has been removed (singulated) from the frame member 305, by a cutting or punching process, in accordance with a preferred embodiment of the present invention. The semiconductor device 700 has also undergone some additional processing such as trim and form operations in which ends of the lead fingers 325 and 335 have been bent to form mounting feet 705. The mounting feet 705 provide for mounting and electrically coupling the semiconductor device 700 to mounting pads of a circuit board.

As will be apparent to a person skilled in the art, the intermediate lead fingers 325 extend from a periphery 710 of the device 700 towards the die pad 310 and the intermediate lead fingers 325 each have their bonding end 330 near the die pad 310. Each outer lead finger 335 also extends from the periphery 710 of the device 700 towards the die pad 310 with the two spaced longitudinal regions 350, 355 each having their bonding region 360, 365 near the die pad 310.

Referring to FIG. 8 there is illustrated a partial side view of the semiconductor device 700 in accordance with a preferred embodiment of the present invention. As shown, an underside of all the mounting feet 705 lie in a seating plane P1. In this embodiment, the semiconductor device 700 is in the form of a Quad Flat Package (QFP).

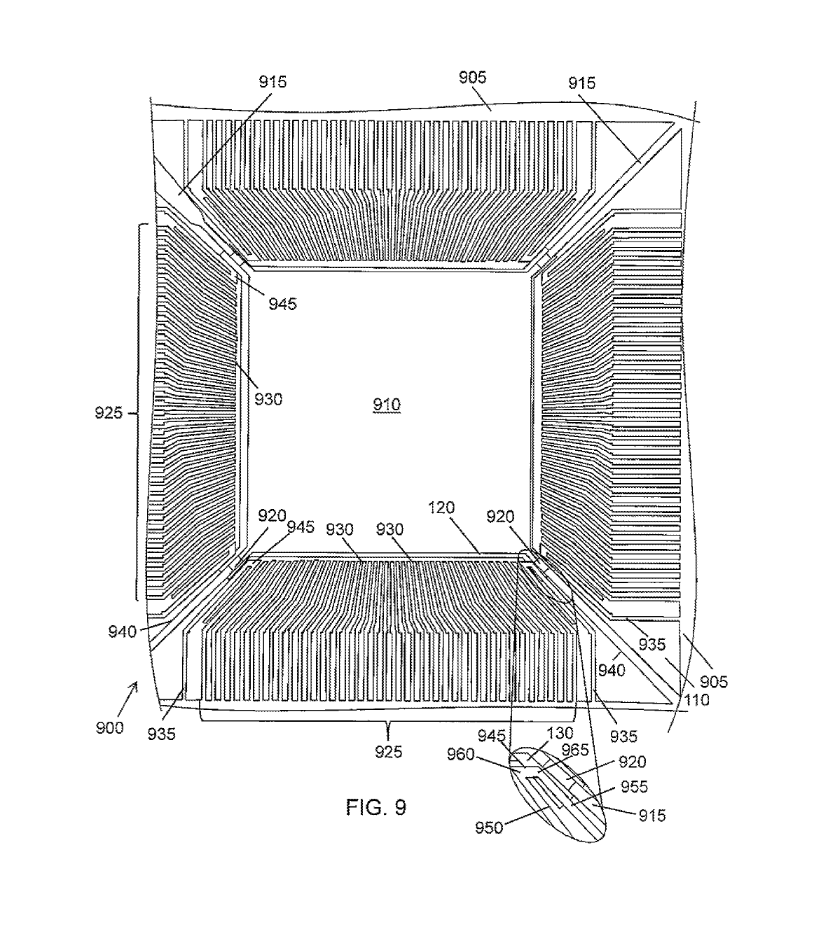

Referring to FIG. 9 there is illustrated a plan view of a lead frame 900 according another embodiment of the present invention, when positioned and supported on the lead frame support 100. The lead frame 900 includes a frame member 905 surrounding a die pad 910, and tie bars 915 that attach the die pad 910 to the frame member 905. The tie bars 915 are bent at an angled section 920 so that die pad 910 is downset from the frame member 905. The die pad 910 is located in and supported by the die pad support region 120 and each angled section 920 is located in a respective one of the slots 130. The lead frame 900 also has a plurality of intermediate lead fingers 925 extending from the frame member 905 towards the die pad 910, the intermediate lead fingers 925 each having a bonding end 930 near the die pad 910. There is also an outer lead finger 935 adjacent a respective edge 940 of each one of the tie bars 915, and each outer lead finger 935 extends from the frame member 905 towards the die pad 910.

Each outer lead finger 935 includes a transverse region 945 coupling two spaced longitudinal regions namely a first longitudinal region 950 and a second longitudinal region 955. The second longitudinal region 955 is located between the first longitudinal region 950 and one of the tie bars 915, and the first and second longitudinal regions 950, 955 each have a respective bonding region 960, 965 near the die pad 910

In this embodiment, the transverse region 945 forms part of the bonding regions 960, 965 of each of the first and second longitudinal regions 950, 955. If required there may also be a support tape, in the shape of a rectangular frame, attached to an underside of the intermediate lead fingers 925 and the longitudinal regions 950, 955.

The lead frame 900 is used to form a semiconductor die package similar to the semiconductor die package 700 and to avoid repetition the bonding, encapsulation, singulation, and trim and form operations are not illustrated or described in detail.

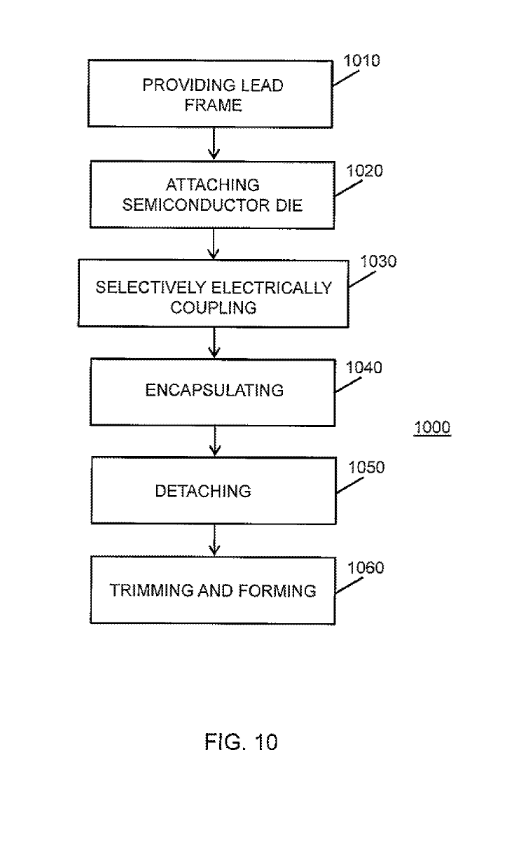

FIG. 10 is a flow chart illustrating a method 1000 of forming a semiconductor die package in accordance with a preferred embodiment of the present invention. The method 1000 will be described, where necessary, mainly with reference to FIGS. 3 to 8 however, the method 1000 is not limited to the specific embodiments of FIGS. 3 to 8 as will be apparent to a person skilled in the art. The method 1000 includes, at a block 1010, providing the lead frame 300 or 900 supported on the lead frame support 100. The lead frame 300 or 900 is supported on a lead frame support 100 so that the die pad 210 is located in and supported by the die pad support region 120 and each angled section 220 is located in a respective one of the slots 130.

At a block 1020 there is performed attaching the semiconductor die 405 to the die pad 310. Next, at a block 1030 there is performed a process of selectively electrically coupling, with the bond wires 505, the connection pads 410 of the semiconductor die 405 to the bonding regions of each outer lead finger. In this embodiment there is no more than one of the bond wires 505 bonded to the bonding region 365 of the second longitudinal region 355. Furthermore, there is typically more than one of the bond wires 505 bonded to the bonding region 360 of the first longitudinal region 350. The process of selectively electrically coupling also includes wire bonding the connection pads 410 of the semiconductor die to bonding ends 330 of the intermediate lead fingers 325.

At an encapsulating block 1040 the semiconductor die 405, the bonds wires 505, the bonding ends 330, bonding regions 360, 365 and the longitudinal regions 360, 365 are encapsulated with the encapsulant 605. At block 1050, the tie bars 315, the intermediate lead fingers 325, and each outer lead finger 335 are detached from the frame member 305 to provide the semiconductor device 700. Trimming and forming may be part of the detaching process or alternatively trimming and forming is performed at a block 1060. The trimming and forming process includes bending ends of all the intermediate lead fingers 325 and an end of each outer lead finger 335 to thereby provide the mounting feet 705 for the semiconductor device 700.

Advantageously, the present invention reduces or at least alleviates potential problems, during wire bonding, caused by unsupported bonding ends of leads being located over the slots 130. Since the outer lead fingers have two spaced longitudinal regions 360, 365 or 960, 965 then no more than one of the bond wires 505 need be bonded to the bonding region 365 or 395. Thus, if the bonding region 365 or 395 is unsupported over one of the slots 130 then the longitudinal region 365 or 395 is only subject to stress, bounce or bending for a single wired bond. Furthermore, the transverse region 345 provides for additional support when the bonding region 365 is over one of the slots 130.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A lead frame, comprising:
a die pad;
a frame member surrounding the die pad;
tie bars attaching the die pad to the frame member, wherein the tie bars are bent so that the die pad is downset from the frame member;
intermediate lead fingers extending from the frame member towards the die pad, the intermediate lead fingers each having a bonding end near the die pad; and
an outer lead finger adjacent a respective edge of each of the tie bars, wherein each outer lead finger extends from the frame member towards the die pad,
wherein each outer lead finger includes two spaced longitudinal regions and a transverse region coupling the two spaced longitudinal regions, and wherein the two spaced longitudinal regions each have a bonding region near the die pad.

2. The lead frame of claim 1, wherein each outer lead finger includes a fork with the transverse region located between the frame member and the bonding region of each of the longitudinal regions.

3. The lead frame of claim 1, wherein the transverse region forms part of the bonding region of each of the longitudinal regions.

4. The lead frame of claim 1, wherein a support tape is attached to an underside of the intermediate lead fingers and the longitudinal regions.

5. A method of forming a semiconductor die package, the method comprising the steps of:
providing a lead frame with a frame member surrounding a die pad, the lead frame having tie bars attaching the die pad to the frame member, the tie bars having an angled section that down sets the die pad from the frame member, intermediate lead fingers extending from the frame member towards the die pad, and an outer lead finger adjacent a respective edge of each one of the tie bars, wherein each outer lead finger extends from the frame member towards the die pad, and wherein each outer lead finger includes a transverse region coupling two spaced longitudinal regions each having a bonding region near the die pad, and wherein the two spaced longitudinal regions are a first longitudinal region and second longitudinal region located between the first longitudinal region and one of the tie bars;
attaching a semiconductor die to the die pad;
selectively electrically coupling, with bond wires, connection pads of the semiconductor die to the bonding regions of each outer lead finger, wherein no more than one of the bond wires is bonded to the bonding region of the second longitudinal region;
encapsulating the semiconductor die and bonding regions with an encapsulant; and
detaching from the frame member the tie bars, the intermediate lead fingers, and each outer lead finger.

6. The method of packaging a semiconductor die of claim 5, further comprising bending ends of all of the intermediate lead fingers and an end of each outer lead finger to form mounting feet.

7. The method of packaging a semiconductor die of claim 5, wherein the selectively electrically coupling is characterized by there being more than one bond wire bonded to the bonding region of the first longitudinal region.

8. The method of packaging a semiconductor die of claim 7, wherein the selectively electrically coupling includes wire bonding the connection pads of the semiconductor die to bonding ends of the intermediate lead fingers.

9. The method of packaging a semiconductor die of claim 5, wherein each outer lead finger includes a fork with the transverse region located between the mounting feet and the bonding region of each of the longitudinal regions.

10. The method of packaging a semiconductor die of claim 8, wherein the transverse region forms part of the bonding region of each of the longitudinal regions.

11. The method of packaging a semiconductor die of claim 5, wherein a support tape is attached to an underside of the intermediate lead fingers and the longitudinal regions.

12. The method of packaging a semiconductor die of claim 5, wherein the providing is characterized by the lead frame being supported on a lead frame support having a recessed central die pad support region and slots, and wherein the die pad is located in and supported by the die pad support region and each angled section is located in a respective one of the slots.

13. A semiconductor device, comprising:
a die pad;
a semiconductor die attached to the die pad;
intermediate lead fingers extending from a periphery of the package towards the die pad, the intermediate lead fingers each having a bonding end near the die pad;
an outer lead finger adjacent a respective edge of each one of a tie bar, each outer lead finger extending from the periphery of the package towards the die pad and wherein each outer lead finger includes two spaced longitudinal regions and a transverse region coupling the two spaced longitudinal regions, wherein the two spaced longitudinal regions each have a bonding region near the die pad;
first bond wires selectively electrically coupling connection pads of the semiconductor die to the bonding regions of the outer lead fingers, wherein only one of the first bond wires is bonded to the bonding region of the second longitudinal region; and
an encapsulant covering the bond wires and the semiconductor die.

14. The semiconductor device of claim 13, further comprising second bond wires selectively connecting the connection pads of the semiconductor die to the bonding ends of respective ones of the intermediate lead fingers.

15. The semiconductor device of claim 14, wherein ends of each outer lead finger are bent to form a mounting foot.

16. The semiconductor device of claim 15, wherein each outer lead finger includes a fork with the transverse region located between the mounting foot and the bonding region of each of the longitudinal regions.

17. The semiconductor device of claim 14, wherein the transverse region forms part of the bonding region of each of the longitudinal regions.

18. The semiconductor device of claim 14, wherein only one first bond wire is connected to the bonding region of the first longitudinal region.

19. The semiconductor device of claim 14, wherein the die pad is downset from the bonding region.

20. The semiconductor device of claim 14, wherein ends of all of the intermediate lead fingers and an end of each outer lead finger are bent to form mounting feet for the semiconductor device.
